(19) United States
(12) Patent Application Publication
(10) Pub. No.: US 2019/0221328 A1
(43) Pub. Date: Jul. 18, 2019

(54) ELECTROMAGNETIC SHIELDING MEMBER, WIRING MODULE, AND METHOD FOR MANUFACTURING ELECTROMAGNETIC SHIELDING MEMBER

(71) Applicants: AUTONETWORKS TECHNOLOGIES, LTD., Yokkaichi-shi, Mie (JP); SUMITOMO WIRING SYSTEMS, LTD., Yokkaichi-Mie (JP); SUMITOMO ELECTRIC INDUSTRIES, LTD., Osaka-shi, Osaka (JP)

(72) Inventors: Takeshi SHIMIZU, Yokkaichi (JP); Masaharu SUETANI, Yokkaichi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 16/303,404

(22) PCT Filed: May 10, 2017
(86) PCT No.: PCT/JP2017/017686

§ 371 Date: Nov. 20, 2018

(30) Foreign Application Priority Data
May 20, 2016 (JP) 2016-101292

(51) Int. Cl. H01B 7/20; H01B 13/22; H02G 1/14; H02G 3/04; H05K 9/00; H01R 43/02

(52) U.S. Cl. CPC H01B 7/20; H01B 13/22; H01R 43/02; H02G 3/04; H05K 9/0081; H02G 1/14

(57) ABSTRACT

An electromagnetic shielding member that includes a metal body with a tube; a tubular conductor that is formed by braiding metal wires into a tubular shape, and has an end arranged on an outer circumferential surface side or an inner circumferential surface side of the tube; a pressing member that presses the tubular conductor against the outer circumferential surface or the inner circumferential surface of the tube; and a bond formed by a filler metal that is melted and solidified to bond the tubular conductor to the tube, the filler metal being separate from the tube, the tubular conductor, and the pressing member.

This application is the U.S. National Phase of PCT/JP2017/017686 filed May 10, 2017, which claims priority from JP 2016-101292 filed May 20, 2016, the entire disclosure of which is incorporated herein by reference.

### BACKGROUND

The present disclosure relates to a technology for providing shielding against electromagnetic noise.

JP 2007-280814A discloses a shielded conductive path provided with a metal pipe, a tubular flexible shielding member connected to an end portion of the pipe, and an annular fixing piece that is fixed annularly to the circumference of the pipe while holding the flexible shielding member together with the peripheral wall of the pipe.

### SUMMARY

Meanwhile, a flexible shielding member or the like that is made of an aluminum braided material has been considered in view of reducing weight and the like. In this case, an oxidized film formed on a surface of an aluminum component hinders reliable connection between the braided material and the pipe. In view of such circumstances and the like, it is conceivable to braze/solder the pipe and the braided material.

However, the braided material, which is formed by braiding a plurality of thin bare wires, is easily bend, and it is difficult to keep it pressed against the circumference of the pipe. Furthermore, a melted filler metal is likely to spread to nearby areas. Accordingly, it is difficult to braze/solder the braided material around the pipe.

An exemplary aspect of the disclosure enables easy brazing/soldering of a tubular conductive member that is formed by braiding metal wires into a tubular shape to a tube portion.

To solve the aforementioned problems, according to a first aspect, an electromagnetic shielding member includes: a metal body with a tube; a tubular conductor that is formed by braiding metal wires into a tubular shape, and has an end arranged on an outer circumferential surface side or an inner circumferential surface side of the tube; a pressing member that presses the tubular conductor against the outer circumferential surface or the inner circumferential surface of the tube; and a bond formed by a filler metal that is melted and solidified to bond the tubular conductor to the tube, the filler metal being separate from the tube, the tubular conductor, and the pressing member.

A second aspect is directed to the electromagnetic shielding member according to the first aspect, wherein the pressing member is a ring that presses the tubular conductor against the outer circumferential surface or the inner circumferential surface of the tube in an entire circumferential direction of the tube, and the bond extends along the circumferential direction of the ring.

A third aspect is directed to the electromagnetic shielding member according to the first or second aspect, wherein at least one of the tube and the tubular conductor is made of aluminum or an aluminum alloy.

A fourth aspect is directed to the electromagnetic shielding member according to the third aspect, wherein both the tube and the tubular conductor are made of aluminum or an aluminum alloy.

A fifth aspect is directed to the electromagnetic shielding member according to the third or fourth aspect, wherein the bond is formed by the filler metal that is made of an aluminum alloy containing silicon and is melted and solidified to bond the tubular conductor to the tube.

A sixth aspect is directed to the electromagnetic shielding member according to any one of the third to fifth aspects, wherein the pressing member is made of aluminum or an aluminum alloy.

A seventh aspect is directed to the electromagnetic shielding member according to any one of the first to sixth aspects, wherein the bond is interposed between the tube and the pressing member to bond the tubular conductor to the tube.

An eighth aspect is directed to the electromagnetic shielding member according to any one of the first to seventh aspects, wherein pressing members are provided at a plurality of positions spaced apart along an axial direction of the tube, and a bond is interposed between the pressing members provided at the plurality of positions to bond the tubular conductor to the tube.

According to a ninth aspect, a wiring module includes: at least one linear conductor; and the electromagnetic shielding member according to any one of the first to eighth aspects, the electromagnetic shielding member electromagnetically shielding the linear conductor.

To solve the aforementioned problems, according to a tenth aspect, a method for manufacturing an electromagnetic shielding member includes the steps of: (a) arranging an end of a tubular conductor that is formed by braiding metal wires into a tubular shape on an outer circumferential surface side or an inner circumferential surface side of a tube of a metal body; (b) arranging a pressing member on the outer circumferential surface side or the inner circumferential surface side of the tube so that the pressing member presses the tubular conductor against the outer circumferential surface or the inner circumferential surface of the tube; (c) arranging a filler metal at a position, on the outer circumferential surface side or the inner circumferential surface side of the tube, at which the end of the tubular conductor is arranged, the filler metal being separate from the tube, the tubular conductor, and the pressing member; and (d) melting the filler metal and allowing the melted filler metal to solidify so that the filler metal bonds the tubular conductor to the tube, the step (d) being performed after the steps (a), (b), and (c).

An eleventh aspect is directed to the method for manufacturing an electromagnetic shielding member according to the tenth aspect, wherein in the step (d), the melted filler metal flows into a space between the tube and the pressing member, and solidifies therebetween to bond the tubular conductor to the tube.

A twelfth aspect is directed to the method for manufacturing an electromagnetic shielding member according to the tenth or eleventh aspect, wherein, in the step (b), pressing members are arranged at a plurality of positions spaced apart along an axial direction of the tube, in the step (c), the filler metal is arranged at a position between the pressing members arranged at the plurality of positions; and in the step (d), the melted filler metal solidifies, while being retained between the pressing members arranged at the plurality of positions, to bond the tubular conductor to the tube.

According to the first to ninth aspects, brazing/soldering can be performed in a state in which the pressing member presses the tubular conductor against the outer circumferential surface or the inner circumferential surface of the tube. Furthermore, the melted filler metal bonds the tubular conductor to the tube, and thus is unlikely to spread to nearby areas. Accordingly, it is possible to easily braze/solder the tubular conductor, which is formed by braiding metal wires into a tubular shape, to the tube.

According to the second aspect, brazing/soldering can be performed in a state in which the pressing member presses the tubular conductor against the outer circumferential surface or the inner circumferential surface of the tube in the entire circumferential direction of the tube. Furthermore, the bond that extends in the entire circumferential direction of the ring can be used to bond the tubular conductor to the outer circumference of the tube.

According to the third aspect, it is possible to braze/solder the tubular conductor to the tube while breaking or removing, during the brazing/soldering, an oxidized film formed on the surface of at least one of the tube and the tubular conductor made of aluminum or an aluminum alloy.

According to the fourth aspect, since both the tube and the tubular conductor are made of aluminum or an aluminum alloy, it is possible to reliably braze/solder the tube and the tubular conductor while reducing the weight.

An aluminum alloy containing silicon has a melting point lower than that of aluminum, and is suitable for brazing/soldering of aluminum or an aluminum alloy. According to the fifth aspect, such an alloy is used as a filler metal that facilitates bonding of the tubular conductor to the tube.

According to the sixth aspect, when a filler metal suited to be used with aluminum or an aluminum alloy is used, the bond favorably adheres to the pressing member as well. Accordingly, it is also possible to reliably bond the pressing member.

According to the seventh aspect, it is possible to more reliably bond the tubular conductor to the tube on the inner side of the pressing member.

According to the eighth aspect, the melted filler metal can be retained between the plurality of pressing members, and, in this portion, the tubular conductor can be bonded to the tube.

According to the ninth aspect, brazing/soldering can be performed in a state in which the pressing member presses the tubular conductor against the outer circumferential surface or the inner circumferential surface of the tube. Furthermore, the melted filler metal bonds the tubular conductor to the tube, and thus is unlikely to spread to nearby areas. Accordingly, in the wiring module provided with the linear conductor and the electromagnetic shielding member, it is possible to easily braze/solder the tubular conductor that is formed by braiding metal wires into a tubular shape to the tube.

According to the method for manufacturing an electromagnetic shielding member of the tenth aspect, brazing/soldering can be performed in a state in which the pressing member presses the tubular conductor against the outer circumferential surface or the inner circumferential surface of the tube. Furthermore, the melted filler metal bonds the tubular conductor to the tube, and is unlikely to spread to nearby areas. Accordingly, it is possible to easily braze/solder the tubular conductor that is formed by braiding metal wires into a tubular shape to the tube.

According to the eleventh aspect, it is possible to more reliably bond the tubular conductor to the tube on the inner side of the pressing member.

According to the twelfth aspect, the melted filler metal can be retained between the plurality of pressing members, and, in this portion, the tubular conductor can be bonded to the tube.

### BRIEF DESCRIPTION OF THE DRAWINGS

FIG. 1 is a schematic cross-sectional view of a wiring module according to an embodiment.

FIG. 2 is a side view illustrating a coupling portion between a metal pipe and a tubular conductive member.

FIG. 3 is a partial cross-sectional view of the coupling portion between the metal pipe and the tubular conductive member.

FIG. 4 is a diagram illustrating an example of a method for manufacturing an electromagnetic shielding member.

FIG. 5 is a diagram illustrating the example of the method for manufacturing an electromagnetic shielding member.

FIG. 6 is a diagram illustrating the example of the method for manufacturing an electromagnetic shielding member.

FIG. 7 is a diagram illustrating the example of the method for manufacturing an electromagnetic shielding member.

FIG. 8 is a diagram illustrating the example of the method for manufacturing an electromagnetic shielding member.

FIG. 9 is a diagram illustrating the example of the method for manufacturing an electromagnetic shielding member.

FIG. 10 is a side view illustrating a coupling portion between the metal pipe and the tubular conductive member according to a modification.

FIG. 11 is a partial cross-sectional view of the coupling portion between the metal pipe and the tubular conductive member according to this modification.

FIG. 12 is a diagram illustrating an example of a method for manufacturing an electromagnetic shielding member according to this modification.

FIG. 13 is a diagram illustrating the example of the method for manufacturing an electromagnetic shielding member according to this modification.

FIG. 14 is a side view illustrating a coupling portion between the metal pipe and the tubular conductive member according to another modification.

### DETAILED DESCRIPTION OF EMBODIMENTS

### Overall Configuration

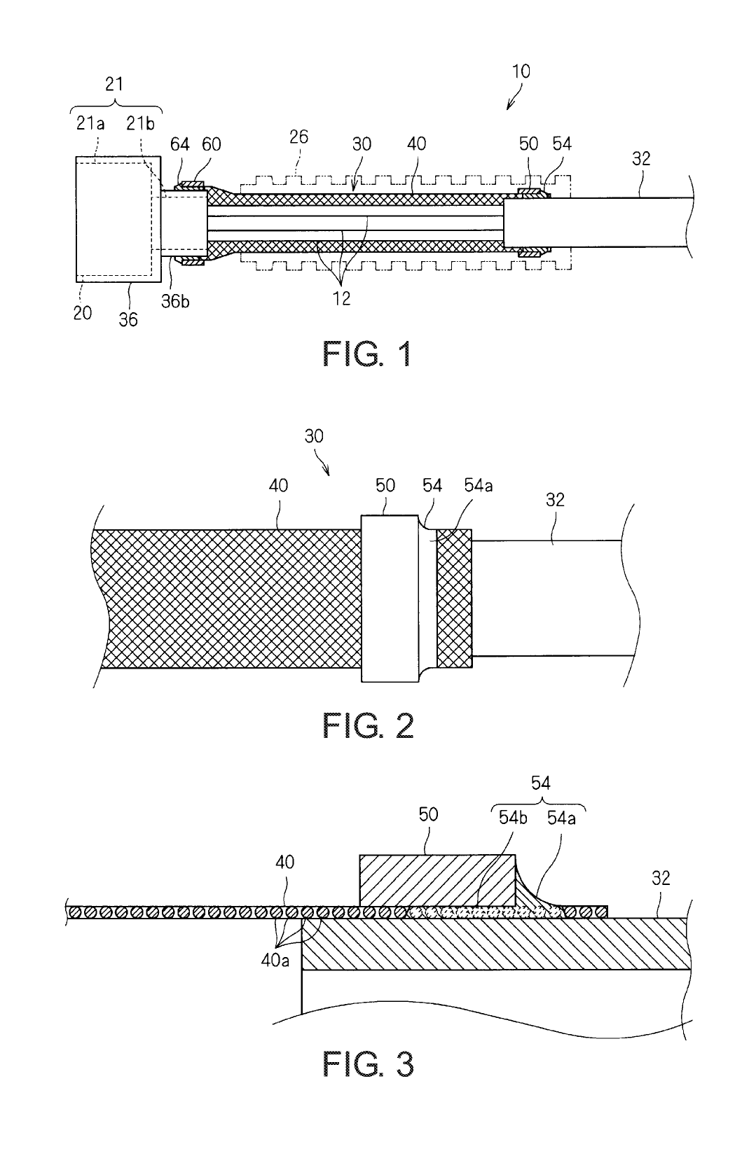

Hereinafter, an electromagnetic shielding member according to an embodiment will be described. Here, first, an overall configuration of a wiring module 10 to which an electromagnetic shielding member 30 is applied will be described. FIG. 1 is a schematic cross-sectional view showing the wiring module 10.

The wiring module 10 is provided with: a plurality of coated electric wires 12, which serve as at least one linear conductor; a connector 20, which serves as an end part attached to end portions, on one side, of the plurality of coated electric wires 12; the electromagnetic shielding member 30; and an external protection member 26.

Here, the plurality of coated electric wires 12 are bundled together into a single bundle. The coated electric wires 12 each include a core wire and a coating that coats the circumference of the core wire. The core wire is a linear member made of a metal such as copper, a copper alloy, aluminum, or an aluminum alloy. The core wire may be configured by a plurality of bare wires twisted together or may be configured by a single wire. The coating is an insulating member made of resin or the like, and is formed so as to cover the core wire through extrusion coating or the like. Note that only one coated electric wire 12 may also be used. Furthermore, the coated electric wires 12 are not necessarily linear conductive wires but may be, instead, bare conductors without a coating on the circumferences thereof. In this case, it is preferable that the bare conductors be covered circumferentially by a heat shrinkable tube or the like.

The connector 20 is attached to the leading end portions of the plurality of coated electric wires 12. The connector 20 is a member made of an insulating material such as resin. The connector 20 is provided with a housing body 21a whose outer peripheral surface has the shape of that of a solid rectangle, and a coupling portion 21b provided adjacent to one end portion of the housing body 21a (end portion to which the coated electric wires 12 are connected). The coupling portion 21b is narrower (here, in the shape of a solid rectangle) than the housing body 21a.

A housing portion 21 includes assembled terminal portions that correspond to the coated electric wires 12. The terminal portions are respectively connected to the core wires of the coated electric wires 12. A terminal portion and a core wire are connected to each other through ultrasonic welding, resistance welding, soldering, pressure bonding, or the like. Furthermore, the terminal portions are provided inside the housing portion 21 using insert molding or the like in a state in which their connection portions that are to be connected to the conductors of the coated electric wires 12 are embedded inside the housing portion 21 and their connection portions opposite thereto protrude. Connection portions of the terminal portions are exposed to the side of the housing body 21a that is opposite to the coupling portion 21b. These connection portions are portions used to establish connection to external electric components, and are formed in the shape of a round terminal or tubular female terminal with a screw hole, a pin-shaped or tab-shaped male terminal, or the like. The coated electric wires 12 that include core wires connected to terminal portions extend outward from the coupling portion 21b of the housing portion 21.

When the wiring module 10 is mounted in a vehicle, the connector 20 is connected to various electric components installed in the vehicle and the coated electric wires 12 are electrically connected to the electric components.

The electromagnetic shielding member 30 is provided with a metal pipe 32 and a metal shell 36, which serve as metal members/metal bodies, a tubular conductive member 40 (tubular conductor) made of metal wires 40a, and ring members 50 and 60 (rings). The metal pipe 32 is coupled to one end portion of the tubular conductive member 40, and the metal shell 36 is coupled to the other end portion of the tubular conductive member 40. The metal shell 36 covers the outer periphery of the connector 20, and the tubular conductive member 40 and the metal pipe 32 cover the coated electric wires 12 extending from the connector 20. Accordingly, the electromagnetic shielding member 30 electromagnetically shields, from the outside, the electric pathway in which the coated electric wires 12 are connected from the terminals inside the connector. The ring member 50 is provided in a coupling portion between the tubular conductive member 40 and the metal pipe 32, and the ring member 60 is used in a coupling portion between the tubular conductive member 40 and the metal shell 36.

Note that the electromagnetic shielding member 30 is not necessarily provided with both the metal pipe 32 and the metal shell 36. Furthermore, even if the electromagnetic shielding member 30 is provided with both the metal pipe 32 and the metal shell 36, there is no need to apply the coupling configurations using the ring members 50 and 60 to both the coupling portion between the tubular conductive member 40 and the metal pipe 32, and the coupling portion between the tubular conductive member 40 and the metal shell 36.

The metal shell 36 is a member formed by subjecting a metal plate such as aluminum, an aluminum alloy, copper, a copper alloy, stainless steel, or iron to press molding or the like, and has the shape of a box that covers the peripheries of the housing body 21a and the coupling portion 21b of the connector 20. The metal shell 36 is open outward of the coupling portion 21b and the opposite side thereof. When the connector 20 is connected to an electric component, the metal shell 36 is electrically connected not only to this electric component but also a grounded portion of the vehicle.

A tube portion 36b (tube) of the metal shell 36 that encloses the coupling portion 21b covers the end portions of the coated electric wires 12 that are connected to the terminals. The metal shell 36 is an example of a metal member that has the tube portion 36b.

The metal pipe 32 is a tubular member in which the coated electric wires 12 can be arranged. The metal pipe 32 is a metal member made of a metal such as aluminum, stainless steel, or iron. The metal pipe 32 has the functions of covering and protecting the portions of the coated electric wires 12 that are located away from the connector 20, and electromagnetically shielding them. This metal pipe 32 is tubular in its entire extending direction and thus is a type of metal member that has a tube portion. The metal pipe 32 may be formed by putting semi-tubular members together so as to be tubular. The metal pipe 32 may be provided with an insulating coating layer on the outer circumference thereof. The insulating coating layer may be formed by subjecting a heat shrinkable tube to thermal shrinkage, or applying an insulating coating material, for example. Of course, an insulating coating layer may be preferably formed on the metal pipe 32 excluding the portion to which the tubular conductive member 40 is connected.

The reason why the metal pipe 32 is provided at a position distanced from the connector 20 is to allow bending of the coated electric wires 12 between the metal pipe 32 and the connector 20. In other words, the metal pipe 32 is a relatively hard member, and thus also functions to keep the coated electric wires 12 in the shape of a predetermined pathway. However, if entirety of the coated electric wires 12 cannot be bent, it will be difficult to install the wiring module 10 in the vehicle. Accordingly, by making the coated electric wires 12 easy to bend between the metal pipe 32 and the connector 20 when the metal pipe 32 is fixed to the vehicle and the connector 20 is connected to electric components of the vehicle, excellent installation operability can be achieved.

The tubular conductive member 40 is a member formed by braiding the metal wires 40a into a tubular shape. Such a tubular conductive member 40 may be, for example, a braided material formed by braiding metal wires in a tubular shape, or a configuration obtained by rolling up a metal cloth or metal mesh, which has a mesh structure woven so that metal wires intersect each other in horizontal and vertical directions, into a tubular shape.

The end portion, on one side, of the tubular conductive member 40 is laid on an end portion of the metal pipe 32. Furthermore, the ring member 50 is provided on the outer circumference of the portion of the tubular conductive member 40 that is laid on the metal pipe 32. Also, a bonding portion 54 (bond) is formed by a later-described filler metal being melted and solidified to preferably make contact with the metal pipe 32 and the ring member 50, thereby bonding the tubular conductive member 40 to the metal pipe 32. With this, a state is achieved in which the tubular conductive member 40 and the metal pipe 32 are electrically connected to each other, and are mechanically connected to each other so that they do not disengage from each other.

The end portion, on the other side, of the tubular conductive member 40 is laid on the tube portion 36b of the metal shell 36. Furthermore, the ring member 60 is provided on the outer circumference of the portion of the tubular conductive member 40 that is laid on the tube portion 36b. A bonding portion 64 is formed by a later-described filler metal being melted and solidified to preferably make contact with the tube portion 36b and the ring member 50, thereby bonding the tubular conductive member 40 to the tube portion 36b. With this, a state is achieved in which the tubular conductive member 40 and the tube portion 36b are electrically connected to each other, and are mechanically connected to each other so that they do not disengage from each other.

The external protection member 26 covers the portions of the coated electric wires 12 that are located between the connector 20 and the metal pipe 32. A bendable member such as a corrugated tube may preferably be used as the external protection member 26.

### Coupling Portion

The coupling portion between the metal pipe 32 and the tubular conductive member 40 will be described more specifically. Note that the coupling portion of the tube portion 36b of the metal shell 36 and the tubular conductive member 40 has the same configuration as that of the coupling portion between the metal pipe 32 and the tubular conductive member 40, and the following description will be made focusing on the configuration of the coupling portion between the tubular conductive member 40 and the metal pipe 32. FIG. 2 is a side view showing the coupling portion between the metal pipe 32 and the tubular conductive member 40, and FIG. 3 is a partial cross-sectional view of the coupling portion between the metal pipe 32 and the tubular conductive member 40.

That is to say, an end portion of the tubular conductive member 40 is laid on an end portion of the metal pipe 32, and the ring member 50 is fitted onto the outer circumference thereof. Here, the ring member 50 is a member in the shape of a short tube. The ring member 50 is a member made of a metal such as aluminum, an aluminum alloy, copper, or a copper alloy. The inner diameter of the ring member 50 is larger than the outer diameter of the metal pipe 32, and is designed with a size such that the tubular conductive member 40 can be interposed between the ring member 50 and the metal pipe 32. Accordingly, the ring member 50 presses the tubular conductive member 40 against the outer circumferential surface of the metal pipe 32 in the entire circumferential direction of the metal pipe 32.

The bonding portion 54 preferably comes into contact with the metal pipe 32 and the ring member 50, and bonds the tubular conductive member 40 to the metal pipe 32. More specifically, the bonding portion 54 includes: a first bonding portion 54a that is provided at an internal corner between one end face of the ring member 50 and a portion of the outer circumferential surface of the metal pipe 32 that is opposite to the one end face of the ring member 50; and a second bonding portion 54b that is interposed between the inner circumferential surface of the ring member 50 and the outer circumferential surface of the metal pipe 32. In this context, the expression “one object is interposed between two other objects” means that one object is present between two other objects, and thus the second bonding portion 54b is present between the inner circumferential surface of the ring member 50 and the outer circumferential surface of the metal pipe 32. The first bonding portion 54a extends along the circumferential direction of the one end face of the ring member 50, and bonds the tubular conductive member 40 to the outer circumferential surface of the metal pipe 32 along the entire circumferential direction. Also, the second bonding portion 54b extends along the circumferential direction of the inner circumferential surface of the ring member 50, and bonds the portion of the tubular conductive member 40 that is located on the inner circumferential side of the ring member 50 to the outer circumferential surface of the metal pipe 32. Accordingly, the tubular conductive member 40 is bonded to the outer circumferential surface of the metal pipe 32 by the bonding portion 54 at positions on the inner circumferential surface of the ring member 50 and on the outside of the one end face.

The bonding portion may, of course, be formed partially in the circumferential direction of the ring member 50. Furthermore, the bonding portion may include only one of the first bonding portion 54a and the second bonding portion 54b.

The bonding portion 54 is bonded to the surfaces of metal wires 40a of the tubular conductive member 40 in a state of enveloping the metal wires 40a, and is also bonded to the surface of the metal pipe 32. Accordingly, the tubular conductive member 40 is mechanically connected, by the bonding portion 54, to the surface of the metal pipe 32 so as not to disengage therefrom. Furthermore, due to at least one of the facts that the bonding portion 54 itself is made of metal and is thus conductive, and that the bonding portion 54 keeps the tubular conductive member 40 in contact with the metal pipe 32, the bonding portion 54 electrically connects the tubular conductive member 40 to the metal pipe 32.

Various materials are conceivable as the materials of the metal pipe 32 and the tubular conductive member 40.

If at least one of the metal pipe 32 and the tubular conductive member 40 is made of aluminum or an aluminum alloy, an oxidized film will form on the surface of the at least one of the metal pipe 32 and the tubular conductive member 40 that is made of aluminum or an aluminum alloy. This oxidized film hinders the electrical connection between the metal pipe 32 and the tubular conductive member 40. Accordingly, as described above, by bonding the metal pipe 32 and the tubular conductive member 40 to each other using the bonding portion 54, which is formed by melting a filler metal, the oxidized film will be broken or removed when the filler metal is melted. Accordingly, it is possible to realize reliable electrical connection between the metal pipe 32 and the tubular conductive member 40, while reducing the weight by using the metal pipe 32 and the tubular conductive member 40, at least one of which is made of aluminum or an aluminum alloy.

Specifically, if both the metal pipe 32 and the tubular conductive member 40 are made of aluminum or an aluminum alloy, an oxidized film that is formed on the surfaces of both the metal pipe 32 and the tubular conductive member 40 is broken and removed, making it possible to achieve reliable connection between them, while further reducing the weight. Moreover, it is possible to suppress bimetallic corrosion between the metal pipe 32 and the tubular conductive member 40.

Preferably, a filler metal that has wettability to the metal pipe 32, the tubular conductive member 40, and the ring member 50, and has a melting point lower than those of the metal pipe 32, the tubular conductive member 40, and the ring member 50 is selected.

If both the metal pipe 32 and the tubular conductive member 40 are made of aluminum or an aluminum alloy, a filler metal that can be used to braze/solder aluminum or an aluminum alloy can be employed. As an example of such a filler metal, an aluminum alloy containing silicon can be used and, in this case, the bonding portion 54 is formed by the aluminum alloy containing silicon being melted and solidified to bond the tubular conductive member 40 to the metal pipe 32. Note that, if an aluminum alloy containing silicon is used as the filler metal, the melting point can be adjusted according to the ratio of the silicon.

As the ring member 50, a material whose melting point is higher than that of the filler metal and to which the filler metal has excellent wettability can be used. If at least one of the metal pipe 32 and the tubular conductive member 40 is made of aluminum or an aluminum alloy, a filler metal that can be used to braze/solder aluminum or an aluminum alloy is selected. Therefore, a ring member 50 made of aluminum or an aluminum alloy is preferable.

Specifically, if the metal pipe 32, the tubular conductive member 40, and the ring member 50 are made of aluminum or an aluminum alloy, and the filler metal is made of an aluminum alloy (for example, an alloy containing silicon as described above), bimetallic corrosion is unlikely to occur in the bonding portion therebetween.

### Method for Manufacturing an Electromagnetic Shielding Member

An example of the method for manufacturing the electromagnetic shielding member 30 will be described.

First, as shown in FIG. 4, the metal pipe 32 and the tubular conductive member 40 are prepared.

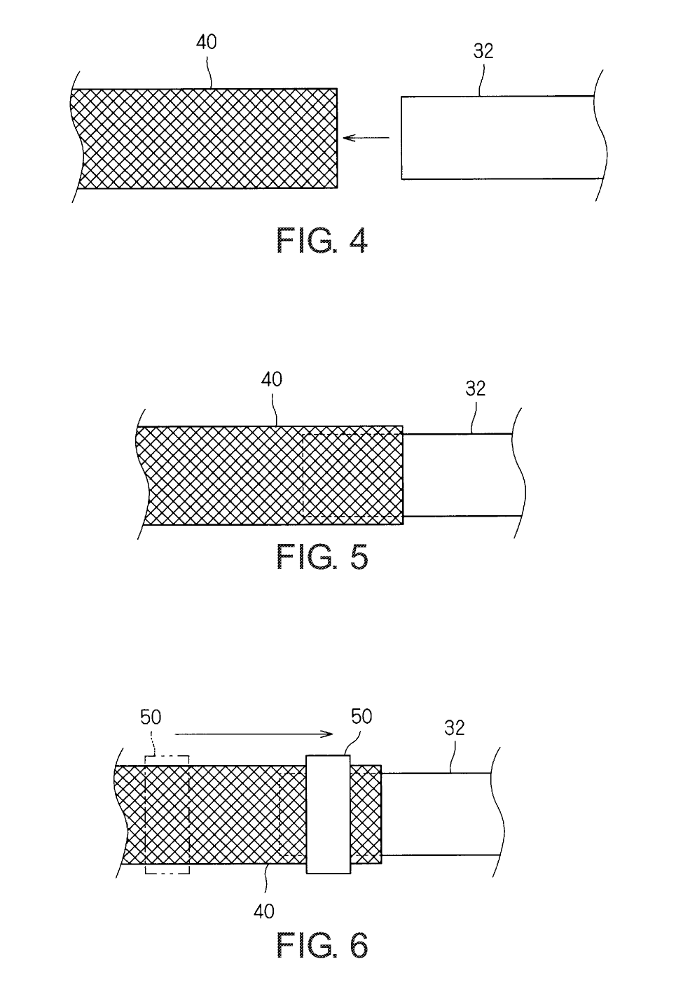

Then, as shown in FIG. 5, an end portion of the metal pipe 32 is inserted into the tubular conductive member 40. Alternatively, an end portion of the tubular conductive member 40 may be laid on the outer circumference of an end portion of the metal pipe 32. Accordingly, the end portion of the tubular conductive member 40 is arranged on the outer circumferential surface side of the metal pipe 32 (step (a)).

Then, as shown in FIG. 6, the ring member 50 is arranged on the outer circumference of the portion of the tubular conductive member 40 that is laid on the metal pipe 32. Accordingly, it is possible to press the tubular conductive member 40 against the outer circumferential surface of the metal pipe 32 (step (b)). This step is preferably performed, for example, by externally fitting the ring member 50 from the end portion side, opposite to the metal pipe 32, of the tubular conductive member 40, and moving the ring member 50 toward the outer circumference of the end portion of the metal pipe 32 along the tubular conductive member 40. Accordingly, it is possible to achieve a state in which the end portion of the tubular conductive member 40 is interposed between the metal pipe 32 and the ring member 50. In this example, only one ring member 50 is used.

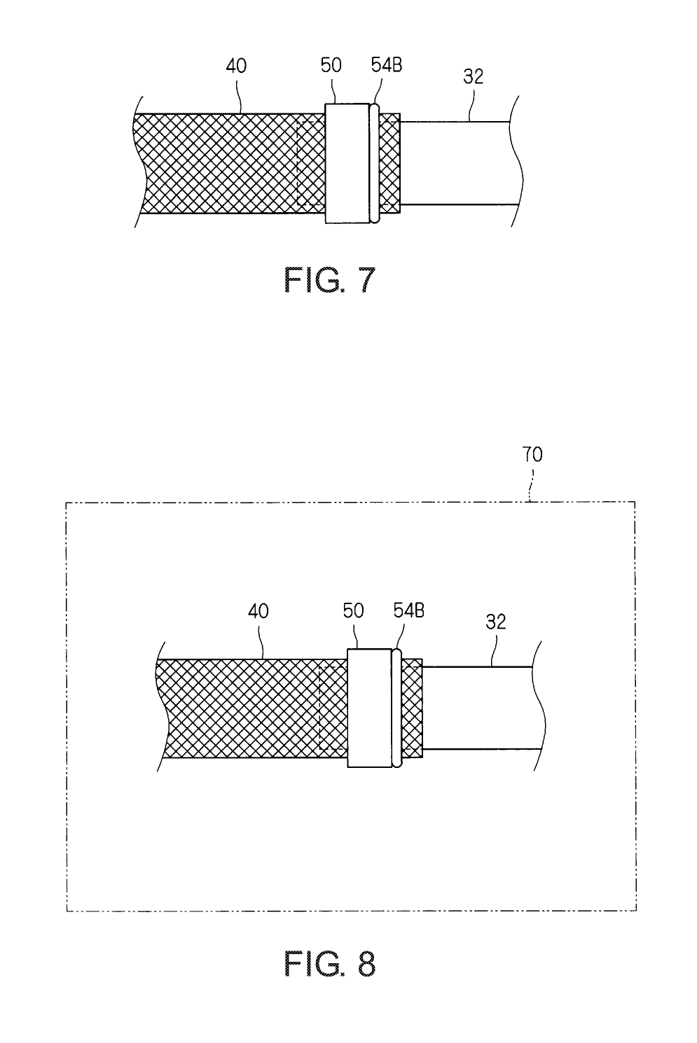

Then, as shown in FIG. 7, a filler metal 54B is arranged at a position, on the outer circumferential surface side of the metal pipe 32, at which the end portion of the tubular conductive member 40 is arranged (step (c)). The filler metal 54B is a solder material, a brazing filler metal, or the like, and a metal is used that has excellent wettability to the metal pipe 32 and the tubular conductive member 40, and has a melting point lower than those of the metal pipe 32 and the tubular conductive member 40. Preferably, the filler metal 54B has excellent wettability also to the ring member 50, and here a description will be given on this assumption. The filler metal 54B is provided as being threadlike for example, and is arranged at the above-described position by being wound around the outer circumference of the tubular conductive member 40 surrounding the metal pipe 32. The number of windings of the filler metal 54B is preferably one or more. The filler metal 54B is preferably arranged at a position adjacent or close to the end face of the ring member 50. The filler metal may also be plate-like or granular.

The above-described steps (a), (b), and (c) may be performed in any order. For example, the filler metal 54B may be wound around the outer circumference of the tubular conductive member 40 surrounding the metal pipe 32, and then the ring member 50 may be arranged at the above-described position. Furthermore, the filler metal 54B may also be wound around the metal pipe 32, then the tubular conductive member 40 may be arranged on the outer circumferential side of the metal pipe 32, and the ring member 50 may be arranged at the above-described position. Alternatively, the filler metal 54B may be attached to and integrated with the ring member 50 in advance, and then the ring member 50 and the filler metal 54B may be attached together at one time to the outer circumference of the tubular conductive member 40 surrounding the metal pipe 32, for example. In this case, by forming a groove on the inner circumference of the ring member for example, and setting the filler metal in the groove, it is possible to integrate the ring member with the filler metal.

Furthermore, the position at which the filler metal 54B is arranged is not limited to the above-described example. For example, the filler metal may also be arranged on the inner circumferential side of the ring member. If the filler metal is arranged on the inner circumferential side of the ring member, it is preferable that the filler metal be arranged at a position other than the position at which the ring member presses the tubular conductive member against the outer circumferential surface of the metal pipe.

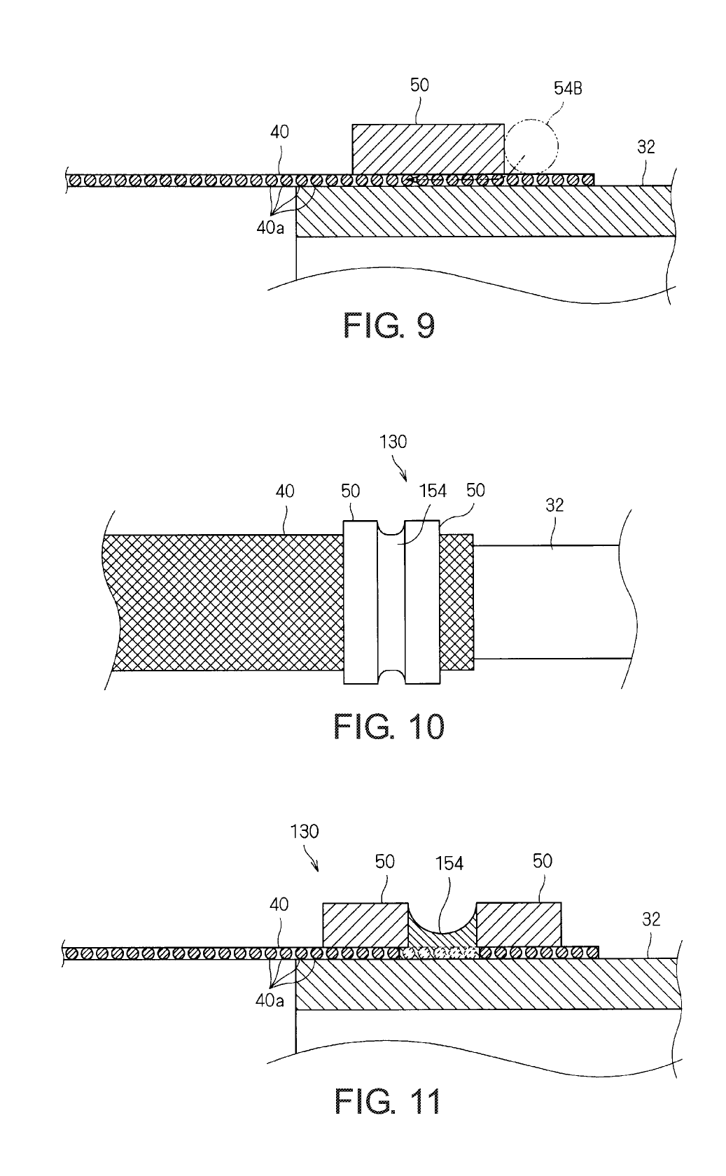

Then, as shown in FIGS. 8 and 9, the filler metal 54B is heated and melted, so that the melted filler metal 54B comes into contact with the metal pipe 32 and the ring member 50, and bonds the tubular conductive member 40 to the metal pipe 32. Heating can be performed by placing the metal pipe 32, the tubular conductive member 40, the metal pipe 32, and the filler metal 54B in a furnace 70, or by using high-frequency induction heating, heating with a burner, or the like. Since the melted filler metal 54B has excellent wettability to the metal pipe 32, the ring member 50, and the tubular conductive member 40, the melted filler metal 54B spreads between the end face of the ring member 50 and the portion of the outer circumferential surface of the metal pipe 32 that is opposite to the end face, while passing through the spaces between the metal wires 40a, and serves as, upon solidifying in this portion, the first bonding portion 54a that bonds the tubular conductive member 40 to the surface of the metal pipe 32. Furthermore, since the melted filler metal 54B has excellent wettability to the metal pipe 32, the ring member 50, and the tubular conductive member 40, the melted filler metal 54B enters, due to capillary action or the like, the gaps between the inner circumferential surface of the ring member 50 and the outer circumferential surface of the metal pipe 32, and spreads while passing through the spaces between the metal wires 40a. Then, upon solidifying between the inner circumferential surface of the ring member 50 and the outer circumferential surface of the metal pipe 32, the melted filler metal 54B serves as the second bonding portion 54b that bonds the tubular conductive member 40 to the surface of the metal pipe 32.

In either case, because the filler metal 54B is melted and then solidified to serve as the bonding portion 54 in a state in which the tubular conductive member 40 is pressed against the metal pipe 32, it is possible to bond to each other the tubular conductive member 40 and the metal pipe 32 that are fixed in the state in which the tubular conductive member 40 is pressed against the metal pipe 32. Furthermore, the melted filler metal 54B accumulates and solidifies adjacent to the position at which the ring member 50 presses the tubular conductive member 40 while extending along the surface of the ring member 50, and serves as the bonding portion 54, and thus, also in view of this, the tubular conductive member 40 can be reliably bonded to the metal pipe 32.

### Effects and the Like

According to the electromagnetic shielding member 30 and the method for manufacturing the electromagnetic shielding member 30 that have the above-described configurations, the end portion of the tubular conductive member 40 is arranged on the outer circumferential surface of the metal pipe 32 and the ring member 50 is used to press the end portion of the tubular conductive member 40 against the outer circumferential surface of the metal pipe 32, and thus it is possible to perform brazing/soldering in a state in which the ring member 50 presses the tubular conductive member 40 against the outer circumferential surface of the metal pipe 32. Furthermore, the melted filler metal 54B bonds the tubular conductive member 40 to the metal pipe 32, while forming the bonding portion 54, and thus the melted filler metal 54B is unlikely to spread to nearby areas. Accordingly, it is possible to easily braze/solder the tubular conductive member 40, which is formed by braiding the metal wires 40a, to the metal pipe 32.

Furthermore, the ring member 50 presses the end portion of the tubular conductive member 40 against the outer circumference of the metal pipe 32 in the entire circumferential direction of the metal pipe 32, and thus the bonding portion 54 is likely to extend in the entire circumferential direction of the metal pipe 32, and the tubular conductive member 40 can be bonded to the outer circumference of the metal pipe 32 by the bonding portion 54, which extends in the entire circumferential direction of the ring member 50.

Furthermore, if one of the metal pipe 32 and the tubular conductive member 40 is made of aluminum or an aluminum alloy, an oxidized film formed on the surface of the corresponding one of the metal pipe 32 and tubular conductive member 40 that is made of aluminum or an aluminum alloy is broken or removed when brazing/soldering is performed, making it possible to reliably connect the tubular conductive member 40 to the metal pipe 32.

Specifically, if both the metal pipe 32 and the tubular conductive member 40 are made of aluminum or an aluminum alloy, it is possible to achieve reliable connection between the tubular conductive member 40 and the metal pipe 32, while reducing the weight of the electromagnetic shielding member 30.

Furthermore, an aluminum alloy containing silicon has a melting point lower than that of aluminum, and is suitable for brazing/soldering aluminum or an aluminum alloy. By using such an alloy as the filler metal, it is possible to easily bond the tubular conductive member 40 to the metal pipe 32.

Furthermore, if a filler metal 54B suited to be used with aluminum or an aluminum alloy is used, and also a ring member 50 made of aluminum or an aluminum alloy is used, the bonding portion 54 will also be reliably bonded to the ring member 50. Thus, the ring member 50 also contributes to improving the strength of the connection between the tubular conductive member 40 and the metal pipe 32.

Furthermore, since the bonding portion 54 is interposed between the metal pipe 32 and the ring member 50, and bonds the tubular conductive member 40 to the metal pipe 32, it is possible to bond the tubular conductive member 40 to the metal pipe 32 even using a relatively small amount of filler metal. For example, even if only one ring member 50 is used, it is possible to bond the tubular conductive member 40 to the metal pipe 32 using a bonding portion formed inside the ring member 50.

### Modifications

The foregoing embodiment has been described using an example in which the bonding portion 54 is formed on the inner circumferential side and one end face side of the ring member 50, but the present disclosure is not necessarily limited to this configuration.

For example, as an electromagnetic shielding member 130 shown in FIGS. 10 and 11, a plurality of ring members 50 may be provided spaced apart along the axial direction of the metal pipe 32, and a bonding portion 154 may be provided between the plurality of ring members 50 so as to bond the tubular conductive member 40 to the metal pipe 32.

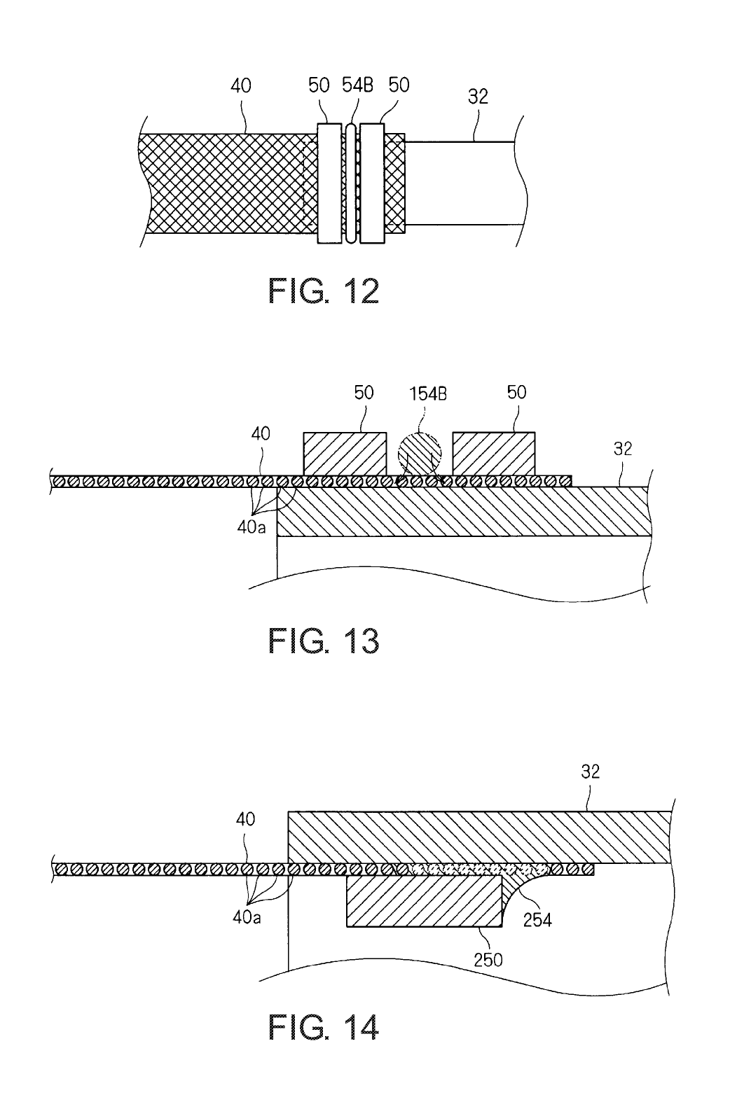

In this case, as shown in FIGS. 12 and 13 for example, preferably the ring members 50 are provided at a plurality of positions spaced apart along the axial direction of the metal pipe 32, and a filler metal 154B is arranged at a position between the plurality of ring members 50, and is heated and melted in this state so as to be retained between the plurality of ring members 50, the melted filler metal 154B then solidifying at this position and serving as the bonding portion 154 that bonds the tubular conductive member 40 to the metal pipe 32.

Also, according to this example, the same effects as those of the foregoing embodiment can be achieved.

Furthermore, with the bonding portion 154 between the plurality of ring members 50, it is possible to more reliably bond the tubular conductive member 40 to the metal pipe 32. Note that, also in this case, part of the bonding portion 154 may enter the space between the metal pipe 32 and the ring member 50.

Furthermore, as a modification shown in FIG. 14, a configuration is also possible in which an end portion of the tubular conductive member 40 is arranged on the inner circumferential surface side of the metal pipe 32, and a ring member 250 is fitted to the inner circumferential surface side thereof so that the end portion of the tubular conductive member 40 is pressed against the inner circumferential surface of the metal pipe 32. In this configuration, a bonding portion 254 comes into contact with the inner circumferential surface of the metal pipe 32 and the ring member 250, and bonds the tubular conductive member 40 to the metal pipe 32.

Also in this case, the same functions and effects as those of the foregoing embodiment can be achieved.

Furthermore, in the foregoing embodiment and modifications, a description was given taking an example in which the ring members 50 and 250 serve as pressing members for pressing the tubular conductive member 40 against the metal pipe 32, but the pressing members are not necessarily ring-shaped. For example, the pressing members may be members that can press the tubular conductive member against the metal pipe at a plurality of positions around the metal pipe, and bonding portions may be formed between the plurality of pressing positions around the metal pipe.

Note that the configurations described in the foregoing embodiment and modifications may be appropriately combined with each other unless they are inconsistent with each other.

For example, in the modification shown in FIG. 14, a plurality of ring members may be provided spaced apart, and a bonding portion may be formed therebetween, similar to the modification shown in FIGS. 12 and 13.

The present disclosure has been described in detail, but the description above is exemplary in all respects, and the present disclosure is not limited to this. Numerous modifications that are not exemplified are construed to be applicable without departing from the scope of the present disclosure.

1. An electromagnetic shielding member comprising:
a metal body with a tube;
a tubular conductor that is formed by braiding metal wires into a tubular shape, and has an end arranged on an outer circumferential surface side or an inner circumferential surface side of the tube;
a pressing member that presses the tubular conductor against the outer circumferential surface or the inner circumferential surface of the tube; and
a bond formed by a filler metal that is melted and solidified to bond the tubular conductor to the tube, the filler metal being separate from the tube, the tubular conductor, and the pressing member.

2. The electromagnetic shielding member according to claim 1,
wherein the pressing member is a ring that presses the tubular conductor against the outer circumferential surface or the inner circumferential surface of the tube in an entire circumferential direction of the tube, and
the bond extends along the circumferential direction of the ring.

3. The electromagnetic shielding member according to claim 1,
wherein at least one of the tube and the tubular conductor is made of aluminum or an aluminum alloy.

4. The electromagnetic shielding member according to claim 3,
wherein both the tube and the tubular conductor are made of aluminum or an aluminum alloy.

5. The electromagnetic shielding member according to claim 3,
wherein the bond is formed by the filler metal that is made of an aluminum alloy containing silicon and is melted and solidified to bond the tubular conductor to the tube.

6. The electromagnetic shielding member according to claim 3,
wherein the pressing member is made of aluminum or an aluminum alloy.

7. The electromagnetic shielding member according to claim 1,
wherein the bond is interposed between the tube and the pressing member to bond the tubular conductor to the tube.

8. The electromagnetic shielding member according to claim 1,
wherein pressing members are provided at a plurality of positions spaced apart along an axial direction of the tube, and
a bond is interposed between the pressing members provided at the plurality of positions to bond the tubular conductor to the tube.

9. A wiring module comprising:
at least one linear conductor; and
the electromagnetic shielding member according to claim 1, the electromagnetic shielding member electromagnetically shielding the linear conductor.

10. A method for manufacturing an electromagnetic shielding member comprising the steps of:
(a) arranging an end of a tubular conductor that is formed by braiding metal wires into a tubular shape on an outer circumferential surface side or an inner circumferential surface side of a tube of a metal body;
(b) arranging a pressing member on the outer circumferential surface side or the inner circumferential surface side of the tube so that the pressing member presses the tubular conductor against the outer circumferential surface or the inner circumferential surface of the tube;
(c) arranging a filler metal at a position, on the outer circumferential surface side or the inner circumferential surface side of the tube, at which the end portion of the tubular conductor is arranged, the filler metal being separate from the tube, the tubular conductor, and the pressing member; and
(d) melting the filler metal and allowing the melted filler metal to solidify so that the filler metal bonds the tubular conductor to the tube, the step (d) being performed after the steps (a), (b), and (c).

11. The method for manufacturing an electromagnetic shielding member according to claim 10,
wherein, in the step (d), the melted filler metal flows into a space between the tube and the pressing member, and solidifies therebetween to bond the tubular conductor to the tube.

12. The method for manufacturing an electromagnetic shielding member according to claim 10,
wherein, in the step (b), pressing members are arranged at a plurality of positions spaced apart along an axial direction of the tube,
in the step (c), the filler metal is arranged at a position between the pressing members arranged at the plurality of positions; and
in the step (d), the melted filler metal solidifies, while being retained between the pressing members arranged at the plurality of positions, to bond the tubular conductor to the tube.
